(19) United States
(12) Patent Application Publication
(10) Pub. No.: US 2006/0145306 A1
(43) Pub. Date: Jul. 6, 2006

(54) Composition for forming low dielectric thin film comprising porous nanoparticles and method of preparing low dielectric thin film using the same

(75) Inventors: Jin Gyu Lee, Seoul (KR); Hyeon Jin Shin, Suwon-si (KR); Hyun Dam Jeong, Suwon-si (KR)

Correspondence Address: BUCHANAN INGERSOLL PC;(INCLUDING BURNS, DOANE, SWECKER & MATHIS), POST OFFICE BOX 1404, ALEXANDRIA, VA, 22313-1404, US

(73) Assignee: SAMSUNG CORNING CO., LTD., Suwon-si (KR)

(21) Appl. No.: 11/319,449

(22) Filed: Dec. 29, 2005

(30) Foreign Application Priority Data
Dec. 31, 2004 (KR) 2004-118124

(51) Int. Cl. H01L 23/58

(52) U.S. Cl. 257/643

(57) ABSTRACT

A composition for forming a low dielectric thin film, which includes a silane polymer, porous nanoparticles and an organic solvent, and a method of preparing a low dielectric thin film using the same. The low dielectric thin film prepared using the composition of the current invention may exhibit a low dielectric constant and excellent mechanical strength, and thus may be applied to conductive materials, display materials, chemical sensors, biocatalysts, insulators, packaging materials, etc.

### CROSS-REFERENCE TO RELATED PATENT APPLICATION

This non-provisional application claims priority under 35 U.S.C. §119(a) to Korean Patent Application No. 2004-118124 filed on Dec. 31, 2004, which is herein incorporated by reference

### BACKGROUND OF THE INVENTION

1. Field of the Invention

Embodiments of the present invention relate, generally, to a composition for forming a low dielectric thin film comprising porous nanoparticles and a method of preparing a low dielectric thin film using the same. More specifically, embodiments of the present invention relate to a composition for forming a low dielectric thin film comprising porous nanoparticles, which is suitable for use in the formation of a thin film having a low dielectric constant and excellent mechanical strength by virtue of the use of porous nanoparticles functioning as a porogen, and to a method of preparing a low dielectric thin film using the same.

2. Description of the Related Art

With development of techniques for fabricating semiconductors, semiconductor devices have been manufactured to be miniaturized and more and more highly integrated. However, in the highly integrated semiconductor, signal transmission may be impeded due to interference between metal wires. Thus, the highly integrated semiconductor exhibits performance that depends on a signal transmission speed through the wiring. In order to lower resistance and capacitance of the metal wire, it is desired to reduce the capacitance of an interlayer dielectric film in the semiconductor.

Although a silicon oxidation film having a dielectric constant of about 4.0 has been typically used as the interlayer dielectric film of the semiconductor, it has reached its functional limits due to an increase of the integration of the semiconductor. Therefore, attempts to decrease the dielectric constant of the dielectric film have been made. In this regard, U.S. Pat. Nos. 3,615,272, 4,399,266, 4,756,977, and 4,999,397 disclose methods of manufacturing an interlayer dielectric film of a semiconductor using polysilsesquioxane having a dielectric constant of about 2.5 to 3.1.

Further, with the aim of reduction of the dielectric constant of the interlayer dielectric film of the semiconductor to 3.0 or less, a porogen-template method has been proposed, which includes mixing a siloxane-based resin with a porogen, and pyrolyzing the porogen at a temperature ranging from 250 to 350° C. to remove it.

U.S. Pat. No. 6,270,846 discloses a method of manufacturing a porous, surfactant-templated thin film, which includes mixing a precursor sol, a solvent, water, a surfactant and a hydrophobic polymer, applying the mixture on a substrate, and evaporating a portion of the solvent to form a thin film, which is then heated.

U.S. Pat. No. 6,329,017 discloses a method of manufacturing a low dielectric thin film, including mixing a silica precursor with an aqueous solvent, a catalyst and a surfactant, to prepare a precursor solution, spin coating a predetermined film with the precursor solution, and removing the aqueous solvent.

U.S. Pat. No. 6,387,453 discloses a method of manufacturing a mesoporous material, including mixing a precursor sol, a solvent, a surfactant and an interstitial compound, to prepare a silica sol, and evaporating a portion of the solvent from the silica sol.

However, such methods suffer because the pores may be connected to each other due to the breakage thereof upon the removal of the porogen or they may be irregularly dispersed, thus decreasing mechanical properties. Therefore, such a porous dielectric film is difficult to apply as an interlayer dielectric film of a semiconductor in terms of various chemical and mechanical processes.

### OBJECTS AND SUMMARY

Accordingly, embodiments of the present invention have been made keeping in mind the above problems occurring in the related art, and an object of embodiments of the present invention is to provide a composition for forming a low dielectric thin film, which can be used to prepare a low dielectric thin film having a low dielectric constant and excellent mechanical strength by using porous nanoparticles.

Another object of embodiments of the present invention is to provide a method of preparing a low dielectric thin film using porous nanoparticles, which can be used to prepare a low dielectric thin film having a low dielectric constant and excellent mechanical strength, with low preparation cost by virtue of a simplified preparation process.

According to an aspect of embodiments of the present invention in order to accomplish the above objects, a composition for forming a low dielectric thin film comprising a silane polymer, porous nanoparticles and a solvent is provided.

According to another aspect of embodiments of the present invention, a composition for forming a low dielectric thin film comprising a silane polymer, porous nanoparticles, a porogen and a solvent is provided.

According to a further aspect of embodiments of the present invention, a composition for forming a low dielectric thin film comprising a silane monomer, porous nanoparticles, a porogen, an acid catalyst and water is provided.

According to still another aspect of embodiments of the present invention, a method of preparing a low dielectric thin film using the above composition comprising the porous nanoparticles is provided.

### BRIEF DESCRIPTION OF THE DRAWINGS

FIG. 1 is a graph showing a dielectric constant and mechanical strength of each of the low dielectric thin films prepared according to a conventional technique and embodiments of the present invention;

FIG. 2A is a view showing an FESEM image of a low dielectric thin film according to a first embodiment of embodiments of the present invention;

FIG. 2B is a view showing an FESEM image of a low dielectric thin film according to a second embodiment of embodiments of the present invention; and

FIG. 3 is a view showing an FESEM image of a low dielectric thin film prepared without the use of porous nanoparticles according to a conventional technique.

### DESCRIPTION OF THE PREFERRED EMBODIMENTS

Hereinafter, a detailed description will be given of embodiments of the present invention, with reference to the appended drawings.

According to an aspect of embodiments of the present invention, a composition for the formation of a low dielectric thin film comprises a silane polymer, porous nanoparticles, and an organic solvent. Such a composition may be applied on a substrate and then heat cured, thereby obtaining a low dielectric thin film having a very low dielectric constant and excellent mechanical strength. The low dielectric thin film thus obtained may be applied as an interlayer dielectric film of a semiconductor, and as well, may have various applications, including conductive materials, display materials, chemical sensors, biocatalysts, insulators, packaging materials, etc.

Although the silane polymer usable in embodiments of the present invention is not particularly limited, it may include, for example, a siloxane homopolymer prepared by hydrolyzing and polycondensing at least one monomer selected from the group consisting of a multi-reactive cyclic siloxane monomer represented by Formula 1 below, an Si monomer having an organic bridge represented by Formula 2 below, and a linear alkoxy silane monomer represented by Formula 3 below in an organic solvent in the presence of an acid catalyst or a base catalyst and water; or a siloxane copolymer prepared by hydrolyzing and polycondensing at least two monomers selected from the monomer group of Formulas 1, 2 and 3 in an organic solvent in the presence of an acid catalyst or a base catalyst and water:

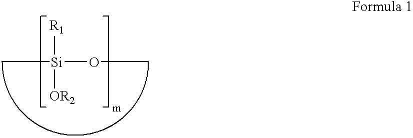

wherein R₁ is a hydrogen atom, a C1 to C3 alkyl group, or a C6 to C15 aryl group; R₂ is a hydrogen atom, a C1 to C10 alkyl group, or SiX₁X₂X₃ (in which X₁, X₂ and X₃ are independently each a hydrogen atom, a C1 to C3 alkyl group, a C1 to C10 alkoxy group, or a halogen atom); and m is an integer ranging from 3 to 8;

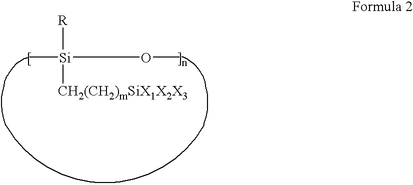

wherein R is a hydrogen atom, a C1 to C3 alkyl group, a C3 to C10 cycloalkyl group, or a C6 to C15 aryl group; X₁, X₂ and X₃ are independently each a C1 to C3 alkyl group, a C1 to C10 alkoxy group, or a halogen group; and n is an integer from 3 to 8, and m is an integer from 1 to 10; and
RSiX₁X₂X₃ Formula 3

wherein R is a hydrogen atom, a C1 to C3 alkyl group, an alkyl or aryl group containing fluorine, a C3 to C10 cycloalkyl group, or a C6 to C15 aryl group; X₁, X₂ and X₃ are independently each a C1 to C3 alkyl group, a C1 to C10 alkoxy group, or a halogen group.

Preferred examples of the cyclic siloxane compound of Formula 1 of embodiments of the present invention include, but are not limited to, a compound (TS-T4Q4) represented by Formula 4 below obtained when R₁ is methyl, R₂ is Si(OCH₃)₃, and m is 4 in Formula 1:

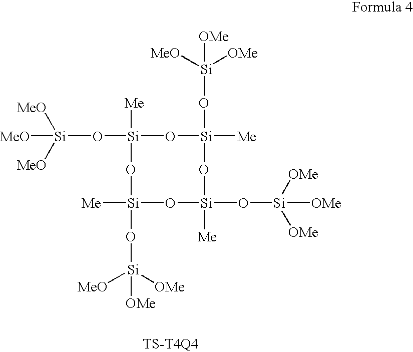

The silane polymer used in embodiments of the present invention preferably has a weight average molecular weight of between 1,000 and 100,000. The silane polymer usable in embodiments of the present invention may include a silsesquioxane polymer, in addition to the above-mentioned siloxane polymer. Particularly, a silsesquioxane polymer, which is selected from the group consisting of hydrogen silsesquioxane, alkyl silsesquioxane, aryl silsesquioxane, and copolymers thereof, may be used.

The silane polymer usable in embodiments of the present invention may be prepared by polymerizing the cyclic siloxane monomer of Formula 2 or copolymerizing it with the linear alkoxy silane monomer of Formula 4.

In addition, the silane polymer usable in embodiments of the present invention may include a silsesquioxane polymer prepared by polymerizing the linear alkoxy silane monomer of Formula 4 or copolymerizing at least two alkoxy silane monomers selected from the alkoxy silane monomer group of Formula 4.

The Si monomer having an organic bridge of Formula 2 preferably includes a compound represented by Formula 5 below:

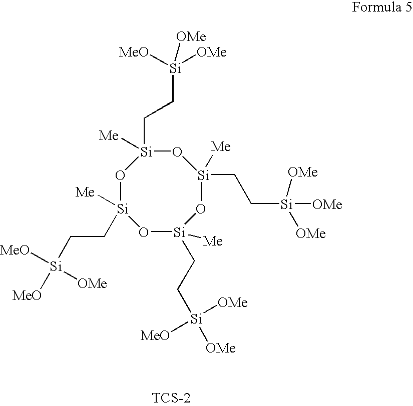

Specifically, examples of the linear alkoxy silane monomer of Formula 3 include, but are not limited to, methyltriethoxysilane, methyltrimethoxysilane, methyltri-n-propoxysilane, phenyltrimethoxysilane, phenyltriethoxysilane, phenyltrichlorosilane, phenyltrifluorosilane, phenethyltrimethoxysilane, methyltrichlorosilane, methyltribromosilane, methyltrifluorosilane, triethoxysilane, trimethoxysilane, trichlorosilane, trifluorosilane, 3,3,3-trifluoropropyl trimethoxysilane, cyanoethyltrimethoxysilane, etc.

The porous nanoparticles usable in embodiments of the present invention may be prepared using a metal precursor, a surfactant, an acid catalyst or a base catalyst, and water. Examples of the porous nanoparticles include, but are not limited to, porous silica, Al₂O₃, B₂O₃, TiO₂, ZrO₂, SnO₂, CeO₂, P₂O₅, Sb₂O₃, MoO₃, ZnO₂, WO₃, and combinations thereof. Preferably, the porous nanoparticles have a diameter of 5-150 nm and, preferably, have pores with a diameter of 2-10 nm.

In embodiments of the present invention, examples of a surfactant, which may be used as a porous template, include, but are not limited to, anionic surfactants, cationic surfactants, and nonionic surfactants or block copolymers. Examples of the anionic surfactant include, but are not limited to, sulfates, sulfonates, phosphates, and carboxylic acids. Examples of the cationic surfactant include, but are not limited to, alkylammonium salts, Gemini surfactants, cetylethylpiperidinium salts, and dialkyldimethylammonium. Examples of the nonionic surfactant include, but are not limited to, any one selected from the group consisting of Brij surfactants, primary amines, poly(oxyethylene)oxide, octaethylene glycol monodecyl ether, octaethylene glycol monohexadecyl ether, octylphenoxypolyethoxy(9-1 0)ethanol (Triton X-100), and polyethyleneoxide-polypropyleneoxide-polyethyleneoxide triblock copolymers.

Examples of the acid catalyst for use in the preparation of porous particles include, but are not limited to, hydrochloric acid, nitric acid, benzene sulfonic acid, oxalic acid, and formic acid. Examples of the base catalyst include, but are not limited to, sodium hydroxide, tetramethylammonium hydroxide (TPAOH), potassium hydroxide, ammonia water, etc.

A composition according to another aspect of embodiments of the present invention comprises not only a silane polymer, porous nanoparticles and a solvent but also a porogen. The porogen usable in embodiments of the present invention includes all of the porogens known for use in the formation of a porous dielectric film. Specifically, examples of the porogen include, but are not limited to, polycaprolactone, α-cyclodextrin, β-cyclodextrin, and γ-cyclodextrin.

In embodiments of the present invention, examples of a surfactant, which may serve as the porogen, include, but are not limited to, anionic surfactants, cationic surfactants, and nonionic surfactants or block copolymers. Examples of the anionic surfactant include, but are not limited to, sulfates, sulfonates, phosphates, and carboxylic acids. Examples of the cationic surfactant include, but are not limited to, alkylammonium salts, Gemini surfactants, cetylethylpiperidinium salts, and dialkyldimethylammonium. Examples of the nonionic surfactant include, but are not limited to, any one selected from the group consisting of Brij surfactants, primary amines, poly(oxyethylene)oxide, octaethylene glycol monodecyl ether, octaethylene glycol monohexadecyl ether, octylphenoxypolyethoxy(9-10)ethanol (Triton X-100), and polyethyleneoxide-polypropyleneoxide-polyethyleneoxide triblock copolymers. The porogen is preferably used in an amount of 0.1 to 70 wt %, based on the total weight of the silane polymer and the porogen in the coating solution, but the amount thereof is not limited thereto. Examples of the surfactant serving as the porogen include, but are not limited to, polyethylene oxide-propylene oxide block copolymer of Formula 6, polyethyleneoxide-propyleneoxide-polyethyleneoxide triblock copolymer of Formula 7, a cyclodextrin derivative of Formula 8, cetyltrimethylammonium bromide (CTAB), octylphenoxypolyethoxy(9-10)ethanol (Triton X-100), and an ethyidiamine alkoxylate block copolymer:

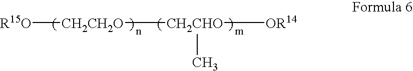

wherein R¹⁴ and R¹⁵ are independently each a hydrogen atom, a C2-C30 acyl group, a C1-C20 alkyl group, or a silicon (Si) compound represented by Sir₁r₂r₃, in which s r₁, r₂ and r₃ are independently each a hydrogen atom, a C1-C6 alkyl group, a C1-C6 alkoxy group, or a C6-C20 aryl group, and m is an integer from 20 to 80 and n is an integer from 2 to 200;

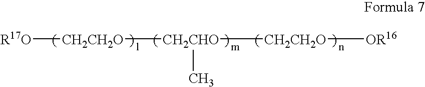

wherein R¹⁶ and R¹⁷ are independently each a hydrogen atom, a C2-C30 acyl group, a C1-C20 alkyl group, or a silicon (Si) compound represented by Sir₁r₂r₃, in which r₁, r₂ and r₃ are independently each a hydrogen atom, a C1-C6 alkyl group, a C1-C6 alkoxy group, or a C6-C20 aryl group, and I is an integer from 2 to 200; and

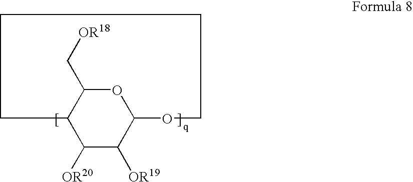

wherein R¹⁸, R¹⁹, and R²⁰ are independently each a hydrogen atom, a C2-C30 acyl group, a C1-C20 alkyl group, or a silicon (Si) compound represented by Sir₁r₂r₃, in which r₁, r₂ and r₃ are independently each a hydrogen atom, a C1-C6 alkyl group, a C1-C6 alkoxy group, or a C6-C20 aryl group, and q is an integer from 5 to 8.

Examples of the organic solvent used in embodiments of the present invention include, but are not particularly limited to, aliphatic hydrocarbon solvents, such as hexane, heptane, etc.; aromatic hydrocarbon solvents, such as anisole, mesitylene, xylene, etc.; ketone-based solvents, such as methyl isobutyl ketone, 1-methyl-2-pyrrolidinone, cyclohexanone, acetone, etc.; ether-based solvents, such as tetrahydrofuran, isopropyl ether, etc.; acetate-based solvents, such as ethyl acetate, butyl acetate, propylene glycol methyl ether acetate, etc.; alcohol-based solvents, such as isopropyl alcohol, butyl alcohol, ethyl alcohol, etc.; amide-based solvents, such as dimethylacetamide, dimethylformamide, etc.; silicon-based solvents; and combinations thereof.

The composition of embodiments of the present invention preferably includes 1-70 wt % solid content based on the total weight thereof, but the solid content is not limited thereto. As such, the solid component of the composition comprises a siloxane polymer and a porogen. Particularly, it is preferred that the composition of embodiments of the present invention be composed of 1-70 wt % of a silane polymer, 0.1-70 wt % of porous nanoparticles, 0-70 wt % of a porogen based on the weight of the solid content of the composition, and 1-90 wt % of a solvent.

A composition according to a further aspect of embodiments of the present invention comprises a silane monomer, porous nanoparticles, a porogen, an acid or a base, and water. The porous nanoparticles and the porogen are as mentioned above.

Examples of the silane monomer usable in embodiments of the present invention include, but are not limited to, methyltriethoxysilane, methyltrimethoxysilane, methyltri-n-propoxysilane, phenyltrimethoxysilane, phenyltriethoxysilane, phenyltrichlorosilane, phenyltrifluorosilane, phenethyltrimethoxysilane, methyltrichlorosilane, methyltribromosilane, methyltrifluorosilane, triethoxysilane, trimethoxysilane, trichlorosilane, trifluorosilane, 3,3,3-trifluoropropyl trimethoxysilane, cyanoethyltrimethoxysilane, tetraethylorthosilicate, etc.

Examples of the acid catalyst usable in embodiments of the present invention include, but are not limited to, all of the acid catalysts known for preparation of polysilsesquioxane, and preferably hydrochloric acid, nitric acid, benzene sulfonic acid, oxalic acid, and formic acid. Examples of the base catalyst include, but are not limited to, sodium hydroxide, tetramethylammonium hydroxide (TPAOH), potassium hydroxide, etc.

According to still another aspect of embodiments of the present invention, a method of preparing a low dielectric thin film using the above-mentioned composition is provided. The low dielectric thin film of embodiments of the present invention may be prepared by mixing a silane polymer, porous nanoparticles, and an organic solvent together to prepare a coating solution, applying the coating solution on a substrate, and then curing the applied coating solution. Alternatively, a silane monomer, porous nanoparticles, an acid or a base, and water may be mixed together to prepare a coating solution, which is then applied on a substrate and subsequently cured. The composition may further include a porogen.

The substrate is not particularly limited so long as it does not hinder the purposes of embodiments of the present invention. Any substrate that is able to endure heat curing conditions may be used, and includes, for example, a glass substrate, a silicon wafer, a plastic substrate, etc., depending on end uses.

Moreover, examples of a process of coating the substrate with the coating solution include, but are not limited to, spin coating, dip coating, spray coating, flow coating, and screen printing. Of these coating processes, a spin coating process is preferable in terms of convenience and uniformity. In the case of conducting the spin coating process, the spin rate may be preferably controlled in the range of from 800 to 5,000 rpm. After the completion of the coating process, a process of evaporating the solvent to dry the film may be further included, if required. As such, the film may be dried by simply exposing it to external environments, applying a vacuum upon initial curing, or heating it to a relatively low temperature of 200° C. or less. Subsequently, the film is heat cured, thus forming an insoluble film having no cracks. The heating conditions may be controlled depending on the composition of the coating solution. Typically, a pre-heating process at 60-170° C. for a time period from 1 min to 24 hours and then a second heating process at 400-450° C. for a time period from 10 min to 48 hours may be conducted.

When the porogen is included, the heat curing temperature is determined in consideration of the decomposition temperature of the porogen. Particularly, in the case where the ordered structure may be formed using the above-mentioned surfactant, ordering effects may be further increased as a heat curing time is prolonged at a low heat curing temperature.

That is, in the case where the surfactant may be used as the porogen, a two-step heating process may be conducted as mentioned above. In the case where cyclodextrin or polycaprolactone is used as the porogen, it is preferred that a pre-heating process at 60-170° C. for a time period from 1 min to 24 hours, a second heating process at 200-300° C. for a time period from 1 min to 24 hours, and a third heating process at 400-450° C. for a time period from 10 min to 48 hours be continuously conducted.

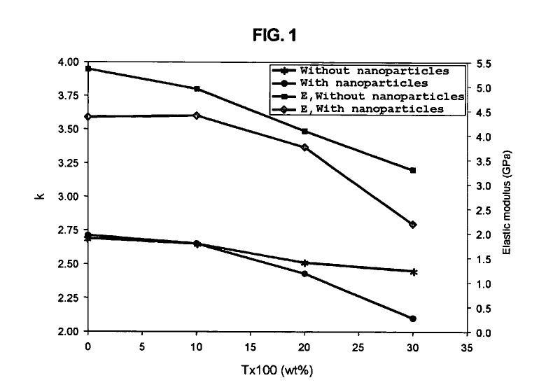

FIG. 1 is a graph showing the dielectric constant and mechanical strength of low dielectric thin films prepared according to a conventional technique and embodiments of the present invention. As shown in FIG. 1, the low dielectric thin film prepared using the method of embodiments of the present invention has a lower dielectric constant and higher mechanical strength than the conventional thin film. Therefore, the low dielectric thin film prepared according to embodiments of the present invention can be applied as the semiconductor interlayer dielectric film of a semiconductor device having high degree of integration.

A better understanding of embodiments of the present invention may be obtained in light of the following examples which are set forth to illustrate, but are not to be construed to limit embodiments of the present invention.

### EXAMPLE 1

Preparation of Silane Polymer A

8.24 mmol of a monomer of Formula 4 (TS-T4Q4) and 3.53 mmol of methyltrimethoxysilane (MTMS, Aldrich) as an alkoxy silane monomer were loaded into a flask, and then diluted with tetrahydrofuran (THF) such that the total concentration of a solution was 0.05-0.07 M. The temperature of the reaction solution was decreased to −78° C. The reaction solution was added with 0.424 mmol of hydrochloric acid and 141.2 mmol of water, the temperature of which was gradually increased from −78° C. to 70° C. At this temperature, the reaction solution was allowed to react for 16 hours. The resultant solution was transferred into a separate funnel, into which diethylether and THF were added in amounts equal to the initially added THF. The reaction solution was washed three times with water corresponding to about 1/10 of the total amount of the solvent, and volatile material was removed under reduced pressure to obtain a white powdery polymer. The polymer thus obtained was dissolved in THF to make a transparent solution, which was then filtered through a filter having 0.2 μm-sized pores. Water was slowly added to the filtrate to precipitate while powder. The white powder was dried at 0-20° C. under 0.1 torr for 10 hours, thus yielding a siloxane polymer A. The amounts of monomer, HCl and water, polymer, Si—OH, Si—OCH₃, and Si—CH₃ are shown in Table 1 below. The amounts of Si—OH, Si—OCH₃ and Si—CH₃ were analyzed using a nuclear magnetic resonator (NMR, Bruker).

TABLE 1

| | TS-T4Q4 | MTMS | HCl | H₂O | Resulting | Si—OH | Si—OCH₃ | Si—CH₃ |
|---|---|---|---|---|---|---|---|---|
| Polymer | (mmol) | (mmol) | (mmol) | (mmol) | Polymer (g) | (%) | (%) | (%) |
| A | 5.09 | 20.36 | 1.222 | 407.2 | 3.70 | 33.60 | 1.30 | 65.10 |

### EXAMPLE 2

Preparation of Silane Polymer B

A siloxane monomer of Formula 5 (TCS-2), having a cyclic structure, and MTMS diluted with 100 ml of THF were loaded into a flask, and the internal temperature of the flask was decreased to −78° C. At −78° C., a predetermined amount of hydrochloric acid (HCl) was diluted with a predetermined amount of deionized water, to which water was slowly added. The temperature of the reaction solution was gradually increased to 70° C., and the solution was allowed to react at 60° C. for 16 hours. Subsequently, the resultant reaction solution was transferred into a separate funnel, added with 150 ml of diethylether, and washed three times with 30 ml of water. The volatile material was removed under reduced pressure from the reaction solution, thus obtaining a white powdery polymer. The polymer thus obtained was dissolved in a small amount of acetone, after which the polymer solution was filtered using a filter having 0.2 μm-sized pores to remove fine powder and impurities. Only the clear solution was slowly added with water. The produced white powder was separated from the solution (mixture solution of acetone and water), and then dried at 0-5° C. under reduced pressure of 0.1 torr, thus yielding a siloxane composition. The amounts of monomer, acid catalyst and water used for synthesis of the precursor and the amount of resulting siloxane resin are given in Table 2 below.

TABLE 2

| | TCS-2 | MTMS | | H₂O | Result. |
|---|---|---|---|---|---|
| Polymer | (mmol) | (mmol) | HCl (mmol) | (mmol) | Polymer (g) |
| B | 3.895 | 35.045 | 0.015 | 506.289 | 4.21 |

### EXAMPLE 3

Preparation of Porous Silica Nanoparticles

In a propylene bottle, a solution of 2.36 g of cetyltrimethylammonium bromide (CTAB) dissolved in 120 g of water was mixed with 9.5 g of 25 wt % aqueous ammonia solution and then uniformly mixed with 10 g of tetraethylorthosilicate (TEOS) at 35° C. The resultant precipitate product was allowed to stand at 80° C. for 72 hours, filtered, and then washed with deionized water. The resultant reaction solution was dried in air at 105° C. for 5 hours, heated to 550° C., and sintered in air, to obtain porous silica nanoparticles.

### EXAMPLES 4-1 TO 44 AND COMPARATIVE EXAMPLE 1

0.75 g of the silane polymer A and 0.005 g of the porous silica nanoparticles were completely dissolved in 4 g of anhydrous ethanol to prepare a coating solution. As such, each coating solution was prepared in varying the weight ratios of silane polymer A and porous silica nanoparticles in Examples 4-1 to 44 as shown in Table 3 below. The coating solution was applied on a silicon wafer at 3000 rpm for 30 sec using a spin coating process, pre-heated at 150° C. for 1.5 hours on a hot plate in a nitrogen atmosphere, and then dried, to prepare a film. The film was heat treated at 420° C. (temperature increase rate: 3° C./min) for 1 hour in a vacuum atmosphere, to manufacture a dielectric film. Thereafter, thickness, refractive index, dielectric constant, hardness and elastic modulus of the dielectric film thus manufactured were measured. The results are given in Table 3 below.

[Measurement of Physical Properties]

The physical properties of the dielectric film were assayed according to the following procedures.

1) Measurement of Dielectric Constant

A silicon heat oxidation film was applied to a thickness of 3000 Å on a boron-doped p-type silicon wafer, and a 100 Å thick titanium layer, a 2000 Å thick aluminum layer, and a 100 Å thick titanium layer were sequentially deposited on the silicon film using a metal evaporator. Subsequently, a dielectric film was formed on the outermost metal layer. On the dielectric film, a 100 Å thick circular titanium thin film and a 5000 Å thick circular aluminum thin film, each having a diameter of 1 mm, were deposited, using a hard mask designed to have an electrode diameter of 1 mm, to obtain an MIM (metal-insulator-metal) structural thin film having a low dielectric constant for use in the measurement of dielectric constants. The capacitance of the thin film thus obtained was measured at frequencies of about 10 kHz, 100 kHz and 1 MHz using a Precision LCR meter (HP4284A) equipped with a micromanipulator 6200 probe station. In addition, the thickness of the thin film was measured using a prism coupler. The dielectric constant was calculated from the following equation:

$$k = \frac{C \times d}{{ɛ}_{0} \times A}$$

wherein k is a dielectric constant, C is a capacitance, ε₀ is a dielectric constant in a vacuum (ε₀=8.8542×10⁻¹² Fm⁻¹), d is a thickness of a dielectric film, and A is a cross-sectional area in contact with an electrode.

2) Thickness and Refractive Index

The thickness and refractive index of the thin film were measured using a prism coupler and an ellipsometer.

3) Hardness and Elastic Modulus

The hardness and elastic modulus of the thin film were quantitatively analyzed using a nanoindenter II available from MTS Co. Ltd. The thin film was indented with the nanoindenter, and the hardness and elastic modulus of the thin film were measured when the indented depth was 10% of the film thickness. The thickness of the thin film was measured using a prism coupler. In the Examples and Comparative Example, in order to assure the reliability of the thin film, six spots on the dielectric film were indented, from which the average value was determined to measure the hardness and elastic modulus of each film.

TABLE 3

| | | | | | Dielect. | | |
|---|---|---|---|---|---|---|---|
| | | | | | Constant | Elastic | |
| | Wt Ratio of | Wt (g) of Silane | Thick. | Refract. | (k) | Modulus | Hardness |
| No. | Silane Polymer:Nanoparticles | Polymer:Nanoparticles | (nm) | Index | 1 MHz | (Gpa) | (Gpa) |
| C. | 16:0 | 0.75:0 | 888 | 1.372 | 2.88 | 8.92 | 1.54 |
| Ex. 1 | | | | | | | |
| Ex. | 16:0.1 | 0.75:0.005 | 982 | 1.379 | 2.73 | 6.21 | 1.05 |
| 4-1 | | | | | | | |
| Ex. | 16:0.2 | 0.75:0.01 | 1025 | 1.357 | 2.64 | 6.32 | 1.04 |
| 4-2 | | | | | | | |
| Ex. | 16:0.4 | 0.75:0.02 | 1345 | 1.345 | 2.66 | 7.16 | 1.25 |
| 4-3 | | | | | | | |
| Ex. | 16:0.6 | 0.75:0.03 | 777 | 1.310 | 2.45 | 7.28 | 1.15 |
| 4-4 | | | | | | | |

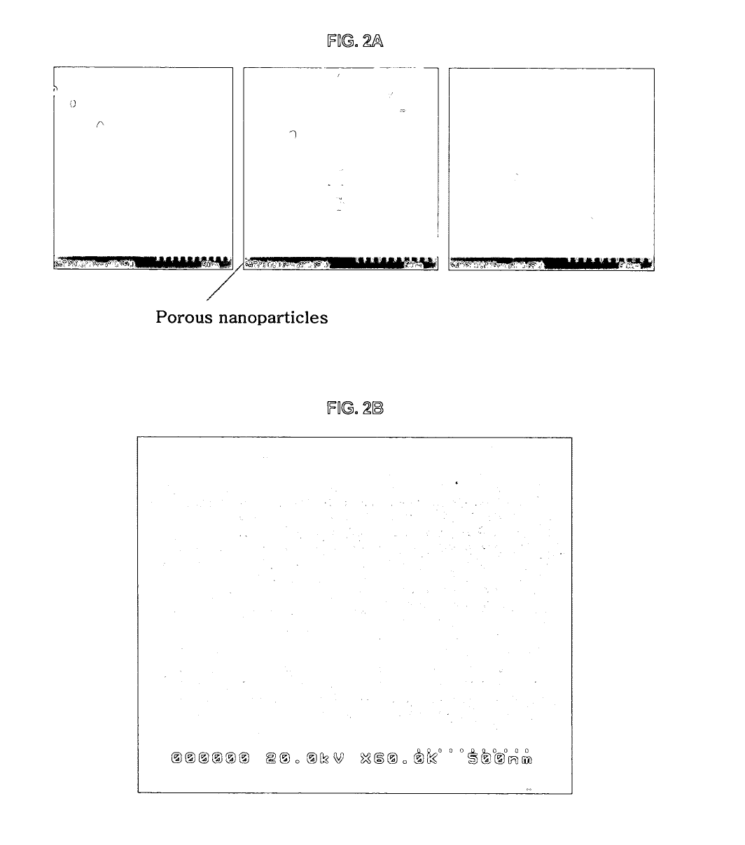

The FESEM image of the low dielectric thin film prepared in Example 4-2 is shown in FIG. 2A. The FESEM image of the low dielectric thin film prepared in Example 4-3 is shown in FIG. 5B. As shown in FIGS. 2A and 2B, the resultant low dielectric thin film is confirmed to be very uniform, without cracks, and to have porous nanoparticles functioning to enhance the mechanical strength thereof and decrease the dielectric constant thereof through the action as pores. Thus, the thin film having the porous nanoparticles has a much lower dielectric constant than a conventional silane polymer matrix thin film (Comparative Example 1) having no porous nanoparticles. In the thin film of embodiments of the present invention, the modulus and hardness are not drastically reduced, and thus superior mechanical properties may be maintained.

### EXAMPLES 5-1 TO 5-3 AND COMPARATIVE EXAMPLE 2

A dielectric film was prepared in the same manner as in Example 4, with the exception that propylene glycol methyl ether acetate (PEGMEA) was used instead of anhydrous ethanol as the solvent upon preparation of the coating solution, and heptakis(2,4,6-tri-O-methyl)-β-cyclodextrin serving as a porogen was further included. The properties of the dielectric film were assayed. The results are given in Table 4 below. Upon formation of the dielectric film, a pre-heating process, at 150° C. and 250° C., respectively for 1 min and a second heating process at 420° C. for 1 hour were sequentially conducted.

TABLE 4

| | | | | | Dielect. | | |
|---|---|---|---|---|---|---|---|
| | | | | | Constant | Elastic | |
| | Wt Ratio of Silane | Wt (g) of Silane | Thick. | Refract. | (k) | Modulus | Hardness |
| No. | Polymer:Porogen:Nanoparticles | Polymer:Nanoparticles | (nm) | Index | 1 MHz | (Gpa) | (Gpa) |
| C. | 18:2:0 | 0.45:0 | 372 | 1.355 | 2.75 | 9.30 | 1.41 |
| Ex. 2 | | | | | | | |
| Ex. | 18:2:0.1 | 0.45:0.0025 | 455 | 1.334 | 2.73 | 8.40 | 1.35 |
| 5-1 | | | | | | | |
| Ex. | 18:2:0.2 | 0.45:0.005 | 518 | 1.336 | 2.40 | 8.61 | 1.39 |
| 5-2 | | | | | | | |
| Ex. | 18:2:0.4 | 0.45:0.01 | 674 | 1.343 | 2.37 | 6.87 | 1.15 |
| 5-3 | | | | | | | |

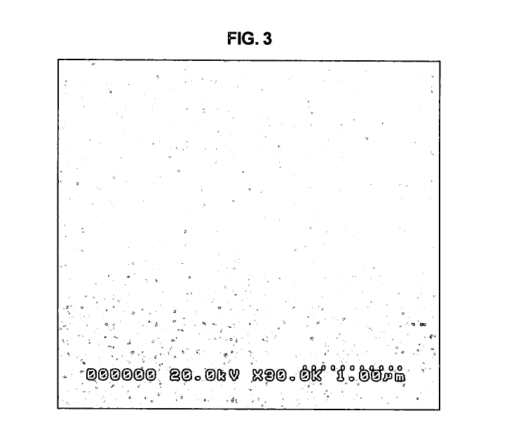

The FESEM image of the low dielectric thin film prepared in Comparative Example 2 is shown in FIG. 3. As shown in FIG. 3, the thin film is confirmed to have no porous nanoparticles.

### EXAMPLES 6-1 TO 6-3 AND COMPARATIVE EXAMPLE 3

A dielectric film was prepared in the same manner as in Example 4, with the exception that the silane polymer B was used upon preparation of the coating solution. The properties of the dielectric film were measured. The results are given in Table 5 below.

TABLE 5

| | | | | | Dielect. | | |
|---|---|---|---|---|---|---|---|
| | | | | | Constant | Elastic | |
| | Wt Ratio of | Wt (g) of Silane | Thick. | Refract. | (k) | Modulus | Hardness |
| No. | Silane Polymer:Nanoparticles | Polymer:Nanoparticles | (nm) | Index | 1 MHz | (Gpa) | (Gpa) |
| C. | 20:0 | 0.75:0 | 1534 | 1.407 | 3.10 | 5.07 | 0.98 |
| Ex. 3 | | | | | | | |
| Ex. | 20:0.1 | 0.75:0.005 | 1598 | 1.399 | 2.85 | 4.65 | 0.86 |
| 6-1 | | | | | | | |
| Ex. | 20:0.2 | 0.75:0.01 | 1939 | 1.397 | 2.68 | 4.96 | 0.95 |
| 6-2 | | | | | | | |
| Ex. | 20:0.4 | 0.75:0.02 | 1998 | 1.391 | 2.59 | 4.39 | 0.87 |
| 6-3 | | | | | | | |

### EXAMPLES 7-1 AND 7-2 AND COMPARATIVE EXAMPLE 4

A dielectric film was prepared in the same manner as in Example 5, with the exception that the silane polymer B was used. The properties of the dielectric film were measured. The results are given in Table 6 below. Upon formation of the dielectric film, a pre-heating process, at 150° C. and 250° C., respectively for 1 min and a second heating process at 420° C. for 1 hour were sequentially conducted.

TABLE 6

| | | | | | Dielect. | | |
|---|---|---|---|---|---|---|---|
| | | | | | Constant | Elastic | |
| | Wt Ratio of Silane | Wt (g) of Silane | Thick. | Refract. | (k) | Modulus | Hardness |
| No. | Polymer:Porogen:Nanoparticles | Polymer:Nanoparticles | (nm) | Index | 1 MHz | (Gpa) | (Gpa) |
| C. | 18:2:0 | 0.9:0 | 1330 | 1.397 | 2.61 | 4.26 | 0.77 |
| Ex. 4 | | | | | | | |
| Ex. | 18:2:0.1 | 0.9:0.005 | 1630 | 1.374 | 2.58 | 4.25 | 0.82 |
| 7-1 | | | | | | | |
| Ex. | 18:2:0.2 | 0.9:0.001 | 564 | 1.367 | 2.40 | 4.60 | 0.77 |
| 7-2 | | | | | | | |

### EXAMPLES 8-1 TO 8-4 AND COMPARATIVE EXAMPLES 5-8

A dielectric film was prepared in the same manner as in Example 4, with the exception that the silane polymer B was used upon preparation of the coating solution, and octylphenoxypolyethoxy(9-10)ethanol (Triton X-100) was used as the porogen. The properties of the dielectric film were measured. The results are given in Table 7 below. Upon formation of the dielectric film, a pre-heating process at 150° C. for 30 min and a second heating process at 420° C. for 1 hour were sequentially conducted.

TABLE 7

| | | | | | Dielect. | | |
|---|---|---|---|---|---|---|---|
| | | | | | Constant | Elastic | |
| | Wt Ratio of Silane | Wt (g) of Silane | Thick. | Refract. | (k) | Modulus | Hardness |
| No. | Polymer:Porogen:Nanoparticles | Polymer:Nanoparticles | (nm) | Index | 1 MHz | (Gpa) | (GPa) |
| C. Ex. 5 | 10:0:0 | 0.5:0 | 930 | 1.403 | 2.69 | 5.35 | 0.90 |
| C. Ex. 6 | 9:1:0 | 0.45:0 | 910 | 1.396 | 2.65 | 4.95 | 0.82 |
| C. Ex. 7 | 8:2:0 | 0.4:0 | 869 | 1.372 | 2.51 | 4.09 | 0.72 |
| C. Ex. 8 | 7:3:0 | 0.35:0 | 786 | 1.351 | 2.45 | 3.30 | 0.57 |
| Ex. | 16:0:0.3 | 0.75:0.03 | 1183 | 1.401 | 2.71 | 4.37 | 0.80 |
| 8-1 | | | | | | | |
| Ex. | 14:1.6:0.3 | 0.675:0.03 | 1107 | 1.384 | 2.65 | 4.40 | 0.79 |
| 8-2 | | | | | | | |
| Ex. | 13:3.0:0.3 | 0.6:0.03 | 1091 | 1.341 | 2.43 | 3.76 | 0.63 |
| 8-3 | | | | | | | |
| Ex. | 11:4.7:0.3 | 0.525:0.03 | 992 | 1.307 | 2.1 | 2.19 | 0.33 |
| 8-4 | | | | | | | |

As previously described herein, embodiments of the present invention provide a composition for forming a low dielectric thin film comprising porous nanoparticles and a method of preparing a low dielectric thin film using the same. According to the method of embodiments of the present invention, the porous nanoparticles included in the thin film function to enhance the matrix and function as pores. Thereby, the low dielectric thin film prepared using the method of embodiments of the present invention can have a low dielectric constant of 3.0 or less and can have improved mechanical strength.

Although the preferred embodiments of embodiments of the present invention have been disclosed for illustrative purposes, those skilled in the art will appreciate that various modifications, additions and substitutions are possible, without departing from the scope and spirit of the invention as disclosed in the accompanying claims.

What is claimed is:

1. A composition for forming a low dielectric thin film, comprising a silane polymer, porous nanoparticles and an organic solvent.

2. The composition as set forth in claim 1, further comprising a porogen.

3. The composition as set forth in claim 1, wherein the silane polymer is a siloxane homopolymer prepared by hydrolyzing and polycondensing at least one monomer selected from the group consisting of a multi-reactive cyclic siloxane monomer of Formula 1, an Si monomer having an organic bridge of Formula 2, and a linear alkoxy silane monomer of Formula 3 in an organic solvent in the presence of an acid catalyst or a base catalyst and water; or a siloxane copolymer prepared by hydrolyzing and polycondensing at least two monomers selected from the monomer group of Formulas 1, 2 and 3 in an organic solvent in the presence of an acid catalyst or a base catalyst and water: 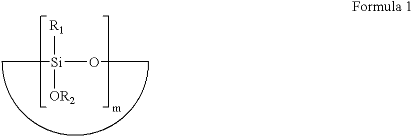
wherein R₁ is a hydrogen atom, a C1 to C3 alkyl group, or a C6 to C15 aryl group; R₂ is a hydrogen atom, a C1 to C10 alkyl group, or SiX₁X₂X₃ (in which X₁, X₂ and X₃ are independently each a hydrogen atom, a C1 to C3 alkyl group, a C1 to C10 alkoxy group, or a halogen atom); and m is an integer from 3 to 8; 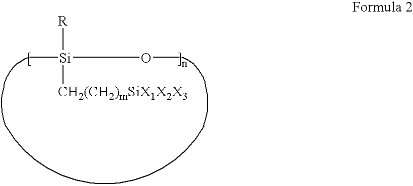
wherein R is a hydrogen atom, a C1 to C3 alkyl group, a C3 to C10 cycloalkyl group, or a C6 to C15 aryl group; X₁, X₂ and X₃ are independently each a C1 to C3 alkyl group, a C1 to C10 alkoxy group, or a halogen group; and n is an integer from 3 to 8, and m is an integer from 1 to 10; and
RSiX₁X₂X₃ Formula 3
wherein R is a hydrogen atom, a C1 to C3 alkyl group, an alkyl or aryl group containing fluorine, a C3 to C10 cycloalkyl group, or a C6 to C15 aryl group; X₁, X₂ and X₃ are independently each a C1 to C3 alkyl group, a C1 to C10 alkoxy group, or a halogen group.

4. The composition as set forth in claim 1, wherein the silane polymer is a silsesquioxane polymer selected from the group consisting of hydrogen silsesquioxane, alkyl silsesquioxane, aryl silsesquioxane, and copolymers thereof.

5. The composition as set forth in claim 1, wherein the porous nanoparticles are formed of at least one selected from the group consisting of SiO₂, Al₂O₃, B₂O₃, TiO₂, ZrO₂, SnO₂, CeO₂, P₂O₅, Sb₂O₃, MoO₃, ZnO₂, and WO₃.

6. The composition as set forth in claim 1, wherein the porous nanoparticles have a diameter of 5-150 nm and have pores with a diameter of 2-10 nm.

7. The composition as set forth in claim 2, wherein the porogen is selected from the group consisting of polycaprolactone, α-cyclodextrin, β-cyclodextrin, and γ-cyclodextrin, or is a surfactant selected from the group consisting of sulfates, sulfonates, phosphates, carboxylic acids, alkylammonium salts, Gemini surfactants, cetylethylpiperidinium salts, dialkyldimethylammonium, Brij surfactants, primary amines, poly(oxyethylene)oxide, octaethylene glycol monodecyl ether, octaethylene glycol monohexadecyl ether, octylphenoxypolyethoxy(9-10)ethanol (Triton X-100), and polyethyleneoxide-polypropyleneoxide-polyethyleneoxide triblock copolymers.

8. The composition as set forth in claim 3, wherein the siloxane compound of Formula 1 is a compound according to Formula 4 below and the Si monomer of Formula 2 is a compound according to Formula 5 below:

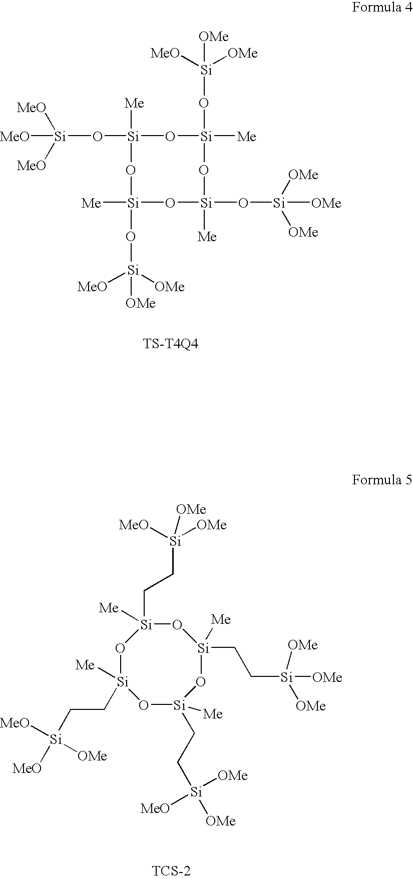

9. The composition as set forth in claim 2, wherein the composition comprises 1-70 wt % of the silane polymer, 0.1-70 wt % of the porous nanoparticles, 0.1-70 wt % of the porogen based on a weight of a solid content of the composition, and 1-90 wt % of the solvent.

10. The composition as set forth in claim 1, wherein the organic solvent is selected from the group consisting of aliphatic hydrocarbon solvents, aromatic hydrocarbon solvents, ketone-based solvents, ether-based solvents, acetate-based solvents, alcohol-based solvents, amide-based solvents, silicon-based solvents, and mixtures thereof.

11. A composition for forming a low dielectric thin film, comprising a silane monomer, porous nanoparticles, a porogen, an acid catalyst or a base catalyst, and water.

12. The composition as set forth in claim 11, wherein the silane monomer is selected from the group consisting of methyltriethoxysilane, methyltrimethoxysilane, methyltri-n-propoxysilane, phenyltrimethoxysilane, phenyltriethoxysilane, phenyltrichlorosilane, phenyltrifluorosilane, phenethyltrimethoxysilane, methyltrichlorosilane, methyltribromosilane, methyltrifluorosilane, triethoxysilane, trimethoxysilane, trichlorosilane, trifluorosilane, 3,3,3-trifluoropropyl trimethoxysilane, cyanoethyltrimethoxysilane, and tetraethylorthosilicate.

13. The composition as set forth in claim 11, wherein the acid catalyst is selected from the group consisting of hydrochloric acid, nitric acid, benzene sulfonic acid, oxalic acid, formic acid, and mixtures thereof, and the base catalyst is selected from the group consisting of sodium hydroxide, tetramethylammonium hydroxide (TPAOH), potassium hydroxide, and mixtures thereof.

14. The composition as set forth in claim 11, wherein the porous nanoparticles are prepared from a metal precursor, a surfactant, an acid catalyst or a base catalyst, and water, and comprise at least one selected from the group consisting of SiO₂, Al₂O₃, B₂O₃, TiO₂, ZrO₂, SnO₂, CeO₂, P₂O₅, Sb₂O₃, MoO₃, ZnO₂, and WO₃.

15. The composition as set forth in claim 11, wherein the porous nanoparticles have a diameter of 5-150 nm, pores of which have a diameter of 2-10 nm.

16. The composition as set forth in claim 11, wherein the porogen is selected from the group consisting of polycaprolactone, α-cyclodextrin, β-cyclodextrin, and γ-cyclodextrin, or is a surfactant selected from the group consisting of sulfates, sulfonates, phosphates, carboxylic acids, alkylammonium salts, Gemini surfactants, cetylethylpiperidinium salts, dialkyldimethylammonium, BRij surfactants, primary amines, poly(oxyethylene)oxide, octaethylene glycol monodecyl ether, octaethylene glycol monohexadecyl ether, octylphenoxypolyethoxy(9-10)ethanol (Triton X-100), and polyethyleneoxide-polypropyleneoxide-polyethyleneoxide triblock copolymers.

17. The composition as set forth in claim 14, wherein the surfactant used to prepare the porous nanoparticles is selected from the group consisting of sulfates, sulfonates, phosphates, carboxylic acids, alkylammonium salts, Gemini surfactants, cetylethylpiperidinium salts, dialkyldimethylammonium, Brij surfactants, primary amines, poly(oxyethylene)oxide, octaethylene glycol monodecyl ether, octaethylene glycol monohexadecyl ether, octylphenoxypolyethoxy(9-10)ethanol (Triton X-100), and block copolymers.

18. The composition as set forth in claim 11, wherein the porogen is used in an amount of 0.1-70 wt % based on the weight of the solid content of the composition, and the porous nanoparticles are used in an amount of 0.1-70 wt %.

19. A method of preparing a low dielectric thin film using porous nanoparticles, comprising applying the composition of claim 1 on a substrate and then curing the composition.

20. The method as set forth in claim 19, wherein the applying of the composition is conducted through spin coating, dip coating, spray coating, flow coating, or screen printing.

21. The method as set forth in claim 19, wherein the curing of the composition is conducted by pre-heating the composition at 60-170° C. for a time period from 1 min to 24 hours and then second-heating the composition at 400-450° C. for a time period from 10 min to 48 hours.

22. The method as set forth in claim 19, wherein the curing of the composition is conducted by pre-heating the composition at 60-170° C. for a time period from 1 min to 24 hours, second-heating the composition at 200-300° C. for a time period from 1 min to 24 hours, and then third-heating the composition at 400-450° C. for a time period from 10 min to 48 hours.

23. A method of preparing a low dielectric thin film using porous nanoparticles, comprising applying the composition of claim 11 on a substrate and then curing the composition.

24. The method as set forth in claim 23, wherein the applying of the composition is conducted through spin coating, dip coating, spray coating, flow coating, or screen printing.

25. The method as set forth in claim 23, wherein the curing of the composition is conducted by pre-heating the composition at 60-170° C. for a time period from 1 min to 24 hours and then second-heating the composition at 400-450° C. for a time period from 10 min to 48 hours.

26. The method as set forth in claim 23, wherein the curing of the composition is conducted by pre-heating the composition at 60-170° C. for a time period from 1 min to 24 hours, second-heating the composition at 200-300° C. for a time period from 1 min to 24 hours, and then third-heating the composition at 400-450° C. for a time period from 10 min to 48 hours.

27. A dielectric film provided between layers of a semiconductor, prepared using the composition of claim 1.

28. A dielectric film provided between layers of a semiconductor, prepared using the composition of claim 2.

29. A dielectric film provided between layers of a semiconductor, prepared using the composition of claim 11.

30. A dielectric film provided between layers of a semiconductor, prepared using the method of claim 19.

31. A dielectric film provided between layers of a semiconductor, prepared using the method of claim 23.
